(19) United States
(12) Patent Application Publication
(10) Pub. No.: US 2010/0118522 A1
(43) Pub. Date: May 13, 2010

(54) LIGHT EMITTING DEVICE USING OLED PANELS IN FOLDED OR DEPLOYED CONFIGURATION

(75) Inventor: Dirk Hente, Wuerselen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/597,522

(22) PCT Filed: Apr. 28, 2008
(86) PCT No.: PCT/IB08/51629

§ 371 Date: Oct. 26, 2009

(30) Foreign Application Priority Data
May 2, 2007 (EP) 07107364.7

(51) Int. Cl. F21L 4/02; H01J 1/62

(52) U.S. Cl. 362/190; 313/1

(57) ABSTRACT

The invention relates to a light emitting device (10), with at least one first (20) and at least one second section (30), wherein the first section (20) borders the second section(30) and each section (20,30) comprises a bottom side (21,31) and at least one side surface (22,32), each section (20,30) comprises a stack of layers (15) of a substrate, with a basic layer (40), a first electrode layer (41), a second electrode layer (42) and an organic light-emitting layer (OLED) (43), wherein the organic light-emitting layer (43) is sandwiched between the first electrode layer (41) and the second electrode layer (42), the organic light-emitting layer (43) is emitting an artificial light (45,45), in an expanded position (100) the first section (20) and the second section(30) are longish stretched and the artificial light (45,45) is primarily emitted through the bottom sides (21,31) of the first section (20) and the second section(30), and in a compact position (110) the first section (20) faces the second section (30) at least partially in such a way, that the artificial light (45,45) is primarily emitted through the side surfaces (22,32) of the first section (20) and the second section (30).

### FILED OF THE INVENTION

This invention relates to a light emitting device.

### BACKGROUND OF THE INVENTION

In different areas of modern life—like e.g. in the field of do-it-yourself-work—different types of illumination devices are needed. On the one hand often a large area lamp is needed to illuminate a workbench or a lathe and on the other hand also illumination devices for small, limited areas are needed.

For the large area illumination often gas discharged lamps are used. Unfortunately, discharge lamps are known to be costly and quite inefficient. To overcome this disadvantage, the use of organic light emitting diodes (OLED) is appropriate. The advantage of the OLED is that it is a homogeneous light source with potentially low costs and high efficiency. Organic light emitting devices (materials and structures) are known in the art, for instant as disclosed in WO2005/053053 A1, the disclosure of which is incorporated herein by reference for all purposes.

In the US 2005 02 48 935 A1 a tiled flat panel lighting system is disclosed. The lighting system comprises a number of light emitting units which are mechanically and electrically interconnected through a number of external connectors. Different arrangements of the light emitting units enable the flat panel lighting system to be individually adjusted to the needs of a user. Unfortunately the disclosed tiled flat panel lighting system can only be used for large area illumination.

### SUMMARY OF THE INVENTION

The invention has for its object to eliminate the above mentioned disadvantages. In particular, it is an object to the invention to provide a light emitting device which combines the ability to illuminate large and point-like limited areas.

The object is achieved by a light emitting device, as told by claim 1 of the present invention. Advantage embodiments of the light emitting device are defined in the sub-claims.

The object of the invention is achieved by a light emitting device with at least one first and at least one second section, wherein the first section borders the second section and each section comprises a bottom side and at least one side surface, each section comprises a stack of layers of a substrate, with a basic layer, a first electrode layer, a second electrode layer and an organic light-emitting layer, wherein the organic light-emitting layer is sandwiched between the first electrode layer and the second electrode layer, the organic light-emitting layer is emitting an artificial light, in an expanded position the first section and the second section are longish stretched and the artificial light is primarily emitted through the bottom sides of the first section and the second section, and in a compact position the first section faces the second section at least partially in such a way, that the artificial light is primarily emitted through the side surfaces of the first section and the second section.

The leading idea of the invention is that the artificial light, generated within the organic light emitting layer is able to leave the light emitting device through the bottom side—for large area illumination—as well as through one of the side surfaces—for illuminating a small area. To achieve this aim the light emitting device is distributed into at least two sections wherein each section comprises a stack of layers, forming an OLED.

Each section of the light emitting device comprises a basic layer, serving as a carrier, which may be made of glass or organic material. Onto this basic layer usually a thin layer of a transparent Indium Tin Oxide (ITO) is applied, forming the first electrode layer. Furthermore, organic light emitting diodes consists of at least one thin layer, with a layer thickness of approximately 5 to 500 nm of organic substances. The OLED is regularly covered with a layer of metal, like aluminum, forming the second electrode layer, whereas the metal layer features a thickness of approximately 100 nm and thus a thickness like the ITO-layer. Aluminum of such a thickness works as a mirror, such that the emission is through the transparent ITO first electrode layer and the transparent basic layer only. In the context of the invention, the term organic light-emitting layer comprises a single layer of an organic material as well as an element, build of several layers, comprising organic and inorganic material.

As the light emitting device possesses a plurality of sections as well as a plurality of light emitting surfaces, different nomenclatures to name each are used. In the context of the invention the term “side surface” describes the edgewise plane of the stack of layers, through which the artificial light is emitted in the compact position. The remaining edgewise planes of the stack of layers are labeled “rim”. Although artificial light may leave the stack of layers through one for the rims, it is not used for illumination as the artificial light leaving the light emitting device through the side surface. The different layers described in the claims of the invention form a stack of layers with a bottom and a top side. In the context of the invention the term “bottom side” describes the lower surface through which the artificial light is leaving the stack of layers. In the contrast to the bottom side, the top side may be coated with a reflective layer so that the artificial light will not leave the stack of layers through this side.

To achieve the object of the invention the disclosed light emitting device possesses two different positions, each resulting in a different type of illumination. In the expanded position the light emitting device forms a longish stretched large area illumination device. In this context the longish stretched arrangement is not limited to a rectangular form but can also include slightly curved or spherically bent arrangements. The sections of the light emitting device may also be arranged in a V- or a W-form, depending on the type of use. In contrast to the described expanded position in the compact position the first and the second section face each other. Aim of this arrangement is to achieve a more compact light emitting device resulting in a smaller illuminated area.

To enable the light emitting device to be transferred from the expanded into the compact position in a preferred embodiment the light emitting device comprises a connection mean, connecting the first section and the second section. The connection mean may be arranged at the side surfaces or rims of the first respectively second section and offer a flexible or bendable connection of the two sections. With the help of the connection mean transfer from the expanded position into the compact position and back is possible. It should not be understood as a limitation if in the following description only the transformation of the light emitting device from the expanded position into the compact position is described. Naturally, the light emitting device is always able to be transferred in both directions from the expanded position into the compact position and again from the compact position into the expanded position.

In a preferred embodiment the light emitting device comprises rectangular sections, being connected through a connection mean. In the compact position the artificial light is emitted through a side surface, wherein an axis of the connection mean forms the surface normal to the side surface. The light emitting side surface of the first and the second section are arranged in one plane in the compact position as well as in the expanded position. In the last named position the side surface form a kind of a line, running alongside the light emitting device. In contrast to that in the compact position the side surfaces form a compact area through which the artificial light is emitted.

In another preferred embodiment the side surfaces of the first and second section are facing each other. So in the expanded position artificial light leaving the first section may well enter the second section through its side surface. If the distance between the side surfaces of the first and second section is small all the light emitted by the organic light emitting layer is either directly leaving the light emitting device through the bottom side or through the side surface. But in the last described case the artificial light will not be illuminating the surrounding but flow into another section where it is reflected and therefore will also leave the light emitting device through the bottom side. Therefore the efficiency of the described embodiment is very high. If the light emitting device is transformed into the compact position, the side surfaces will be aligned along each other forming an illuminating area.

In a preferred embodiment the connection mean may be a hinges, being positioned at the outer rims of the light emitting device respectively sections. Depending on the position of the side surfaces, the hinges may be positioned between two rims of the first and the second section, facing each other. In another embodiment the connection mean may be a stamping, which is inserted in a band like connection mean. The stamping enables the user to bend the sections against each other for the conversion of the light emitting device. If the band like connection mean is made of a metal a cutting may be appropriate, so that just small bridge remain. This type of design of the connection means provide strengths and rigidity for the connection of the two sections. In another embodiment the connection mean may be a foil, connecting the first and second section. The foil may be a thin layer of a polymer material, which is flexible and light weight. Such a foil may also be used as a sealing foil, covering at least parts of the layer structure of the sections.

In another preferred embodiment the first and second sections are not tile like individual pieces but one-piece. Preferably the first and second sections are a flexible one-piece foil. The different layers of the OLED, forming each section, can be embedded on one basic layer. This basic layer may be made of a polymer so that the whole light emitting device may be flexed together to form a cylinder like item. There would be no need for a connection mean because the section itself could be flexed. The first respectively second sections would be arbitrarily chosen parts of the foil. The light emitting side surface may be one of the side faces of the light emitting device. After the flexing the light emitting device would posses a snail shell like form, with the light emitting side surfaces lying in one plane. In the context of the invention the terms “flexing” and “bending” are used to describe the orientation of the sections relative to each other in a manner which deviates from planar. “Flexing” is defined as the curvilinear orientation of the light emitting device in a longitudinal, latitudinal or a diagonal fashion as would occur when material is spiral wrapped or is required to conform to an associated non-planar underlying substrate. “Bending” is used herein to define an action wherein the sheet is folded along a predetermined fold line, permitting the folding of the material.

The organic light emitting layer within the OLED possesses a lambertian characteristic, meaning that the artificial light is evenly spread in all directions. As normally the artificial light should mainly leave the stack of layer through a basic layer respectively a bottom side for illuminating large areas measures are taken to focus and/or reflect the light through the named layers. For the purpose of the described light emitting device it is preferably that the emitted artificial light possesses a bias towards the side surface. Therefore in another preferred embodiment the bottom side of the first and/or second section is covered with a surface layer, enhancing the amount of artificial light, being emitted under an angle with respect to the bottom side. The angle under which the artificial light is bent depends on the position of the side surface. In both positions the artificial light leaving the bottom side will be deflected into the direction of the side surface. But in the compact position, due to the weak deflection the artificial light may enter through a bottom side from a first into a second section, being reflected at one of the electrode layers and again leave the section through the bottom side. This zigzag pass enables the artificial light being primarily emitted through the bottom side to finally reach the side surface and enhance the amount of light being emitted through this surface. To achieve the deflection of the artificial light the surface layer may preferably comprise a structured surface. For example this structured surface may comprise a plurality of micro-prisms, which deflect the artificial light through their outer form and the difference in index of reflection to the surrounding air.

In another preferred embodiment the first and/or the second section comprise a rim, wherein the rim is covered with a reflective layer. As it has been said before all side faces of the sections not being the side surface through which the artificial light is emitted are named rim. To enhance the amount of light leaving the sections through the bottom side and/or the side surface the rim may be covered with a reflective layer. Artificial light hitting the rim is reflected back into the stack of layers with a high probability to leave it through one of the named surfaces.

In another preferred embodiment the second electrode layer may comprise a material or a coating, which is reflecting the artificial light. Often the second electrode layer is made of aluminum, which is not transparent for the artificial light, emitted by the organic light emitting layer. To enhance the amount of artificial light leaving the light emitting device through either the bottom side or the side surface the second electrode layer may be coated with a reflective material. The named material may comprise silver, which reflects a large amount of the artificial light. The coating may also comprise a structure so that the artificial light is not just reflected but also deflected, so that the amount of artificial light possessing a small bias towards the side surface is enlarged.

In another preferred embodiment the first and/or second section are at least partially bordered by a frame mean. The frame mean work as a mounting, which supports the stack of layer. Preferably the frame mean of the first and the second section are connected. Therefore the frame mean enables a user to change the position of the light emitting device from the expanded to the compact position and vice versa. The frame mean also protects the fragile stack of layers from an impact and may also comprise an inner reflective coating. Artificial light leaving the sections through one of the rims may be reflected by the reflective coating of the frame mean back into the stack of layers. In another preferred embodiment the frame mean may also comprise a power source or a switch device. Such devices, circuits and mechanisms include, but are not limited to various on/off switches as well as devices which receive and interpret external environmental input to control the associated switch. It is contemplated that devices such as the described ones would be capable of detecting at least one input condition which can be interpreted and converted into a control signal actionable on an onboard power source in suitable switches associated therewith.

In another preferred embodiment the first and/or the second section comprises a handhold element, wherein the handhold element is arranged in such a way, that in the compact position the light emitting device forms a torch. As has been described it is an object of the invention to disclose a light emitting device which is able to illuminate on the one hand large areas and on the other hand small limited areas. Therefore the light emitting device may be used as a torch. To enable a user to use the light emitting device torch like, the handhold elements may be arranged on the outer rims of the sections. For example the handhold elements may be a metal panel, being connected with the stack of layers. In the compact position the handhold elements may be the outer most layers so that a user can grab the light emitting device on the two metal plates.

Furthermore; the handhold element may comprise a power source and/or a control device and or a switch device. As has been described before these devices and the power source are used to drive and control the light emitting device. Furthermore, the control device may drive and/or control the different sections of the light emitting device to adjust the emitted artificial light of each individual section so that either a large amount of artificial light is emitted through the bottom side or that a large amount of light is emitted through the side surface. In another embodiment the connection mean may be used for an electrical interconnection between the two sections.

The aforementioned light emitting device, as well as claimed components and the components to be used in accordance with the invention in the described embodiments, are not subject to any special exceptions with respect to size, shape, material selection. Technical concepts known in the pertinent field can be applied without limitations. Additional details, characteristics and advantages of the object of the present invention are disclosed in the subclaims and the following description of the respective figures—which are an exemplary fashion only—showing preferred embodiments of the light emitting device according to the present invention.

### BRIEF DESCRIPTION OF THE DRAWINGS

Theses figures are:

FIG. 1 shows a light emitting device with a first and a second section,

FIG. 2 shows the light emitting device in a fully expanded position,

FIG. 3 shows the light emitting device in a partially expanded position,

FIG. 4 shows the light emitting device in a compact position,

FIG. 5 shows a plurality of light rays within the light emitting device,

FIG. 6 shows a one piece light emitting device,

FIG. 7 shows another embodiment of the light emitting device in the compact position and

FIG. 8 shows the light emitting device of FIG. 7 in the expanded position.

### DETAILED DESCRIPTION OF EMBODIMENTS

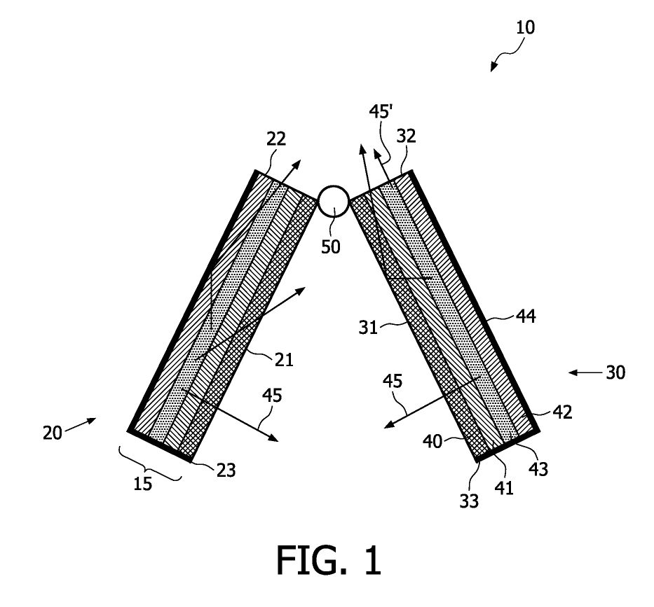

In FIG. 1 the cross section of a light emitting device 10 is shown. The light emitting device 10 comprises a first 20 and a second section 30. The fundament of each section 20, 30 is build by a basic layer 40, being a glass or a polymer substrate. Deposited onto this basic layer 40 is a first electrode layer 41. Above this first electrode layer 41 an organic light emitting layer 43 and a second electrode layer 42 are superimposed onto one another. Each of the three named layers 41, 42, 43 comprises a thickness of less than 500 nm, preferably between 15 nm and 200 nm. Upon application of an electrical current, flowing from one of the electrode layers to the other, the organic light emitting layer 43 emits an artificial light 45 by recombination of electrons and holes in the organic material. If the second electrode layer 42 is made of aluminum it works as a kind of a mirror, reflecting the emitted artificial light 45 through the transparent first electrode layer 41 and the basic layer 30.

To achieve the object of the invention the first 20 and the second section 30 each comprise a bottom side 21, 31 and at least one side surface 22, 32. Artificial light 45 generated within the organic light emitting layer 43 may leave the sections 20, 30 through the bottom sides 21, 31. As will be shown and described below this artificial light is used for large area illumination. Furthermore another part of the artificial light 45′ may leave the sections 20, 30 through the side surfaces 22, 32. This artificial light 45′ will be used to illuminate small areas in a compact position 110 of the light emitting device 10.

The artificial light 45 leaves the first 20 and the second section 30 through the bottom side 21, 31 whereas the artificial light 45′ leaves the sections 20, 30 through the side surfaces 22, 32. The other edgewise parts of the sections 20, 30 are labeled rim 23, 33. The rim 23, 33 of each section 20, 30 may be coated with a reflective coating so that the artificial light 45, 45′ which is emitted by the organic light emitting layer 43 is reflected and deflected back into the stack of layers 15 to achieve a higher efficiency. The same applies for a top layer 44, covering the stack of layers 15. This top layer 44 may also function as a sealing layer, protecting the stack of layers 15 from environmental impacts.

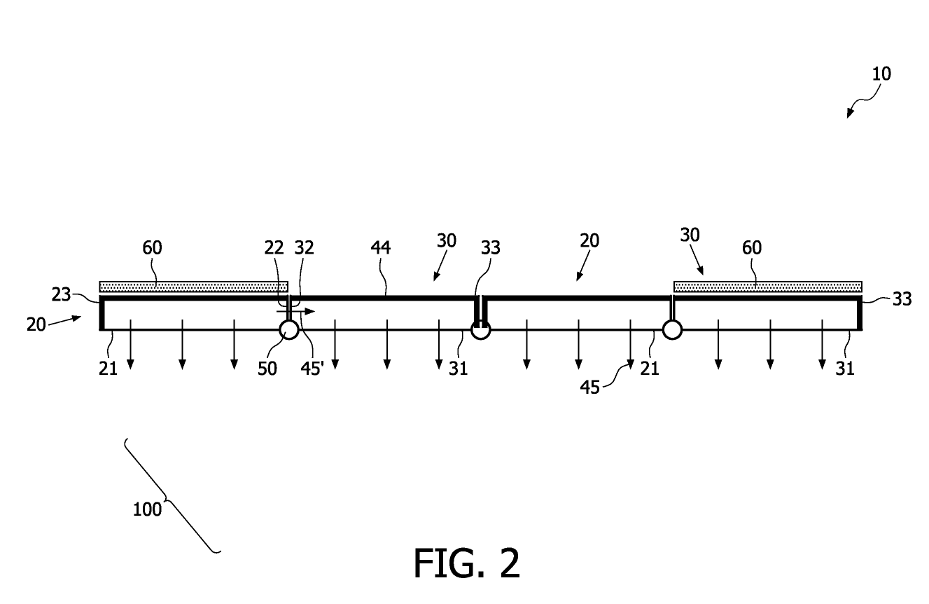

To achieve the object of the invention the light emitting device 10 can either be used as a large area illumination device or as a small point like light source. In FIG. 2 the light emitting device 10 is shown in an expanded position 100. To ease the understanding of the invention the different layers 40, 41, 42, 43 embedded within the sections 20, 30 are not shown. Nevertheless each section 20, 30 has the same composition as those sections shown in FIG. 1. In the expanded position 100 the first section 20 and the second section 30 are arranged in such a way, that they form a longish stretched sheet like light emitting device 10. The artificial light 45 is primarily emitted through the bottom sides 21, 31 of each section 20, 30. In this position 100 the light emitting device 10 can be used to illuminate large areas like desks, workbenches or machines. As the organic light emitting layer 43 comprises a lambertian characteristic the artificial light 45, 45′ is emitted in all directions. To enhance the amount of artificial light 45 emitted through the bottom sides 21, 31 the sections 20, 30 may comprise reflective rims 23, 33 and a reflective top layer 44. As has been shown in FIG. 1 each section comprises a side surface 22, 32 through which the artificial light 45′ is emitted. In the shown expanded position 100 the side surfaces 22, 32 are facing each other. Thus, artificial light 45′ emitted from—e.g.—the first section 20 may flow through the side surface 22 and the side surface 32 into the second section 30. There the artificial light 45 may be reflected or deflected and leave the second section 30 through the bottom side 31.

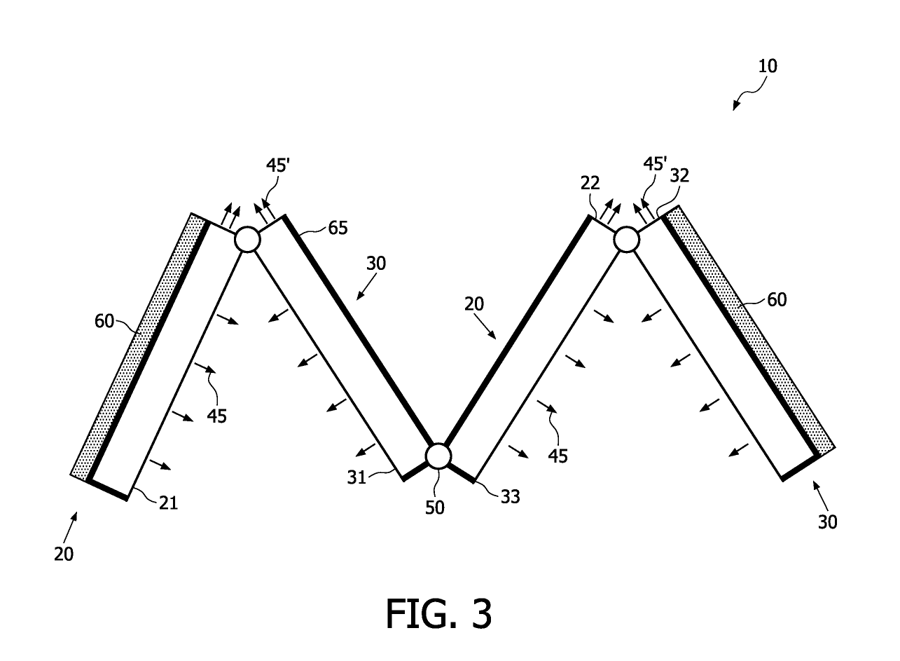

To enable the light emitting device to be converted from the expanded position 100 into the compact position 110 the sections 20, 30 are connected through a connection mean 50. As shown in FIG. 3 the connection mean may be a hinges, being located at the outer ends of each section 20, 30. In the partially compact position shown in FIG. 3 the sections are arranged in a zigzag form, enabling the artificial light 45, 45′ to leave the light emitting device 10 through the bottom side 21, 31 as well as through the side surfaces 22, 32.

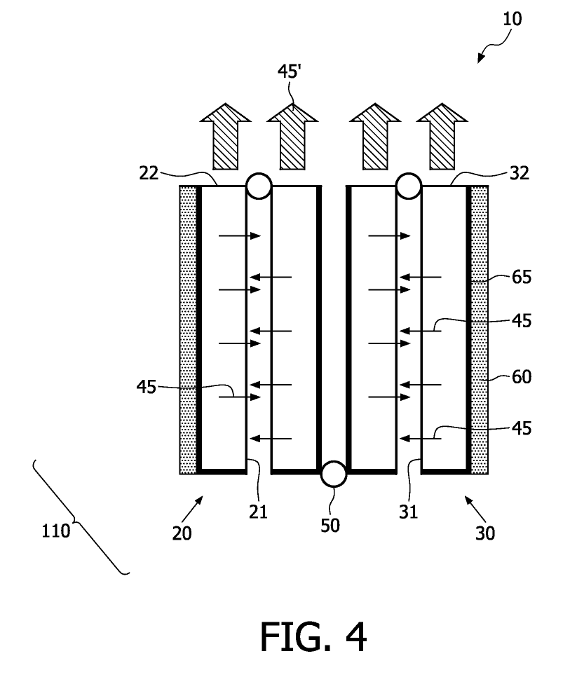

The compact position 110 is shown in FIG. 4. The sections 20, 30 are aligned parallel to each other. The artificial light 45 leaving the section 20 through the bottom side 21 will illuminate the bottom side 31 of the second section 30. The same applies for the artificial light 45 emitted by the second section 30. To achieve the aim of the invention the artificial light 45′ leaving the side surfaces 22, 32 of the sections 20, 30 will form a point like light source, illuminating just a small dedicated area. In the shown embodiment a frame mean 65 boarders each section 20, 30 and works as a mounting for the stack of layers 15. The mounting means 65 of the sections 20, 30 are interconnected by the connection mean 50. The two outer most surfaces of the shown light emitting device 10 comprise a handhold element 60. The handhold element is arranged in such a way, that in the compact position 110 the light emitting device 10 forms a torch. So the light emitting device 10 disclosed by the invention can easily be handled.

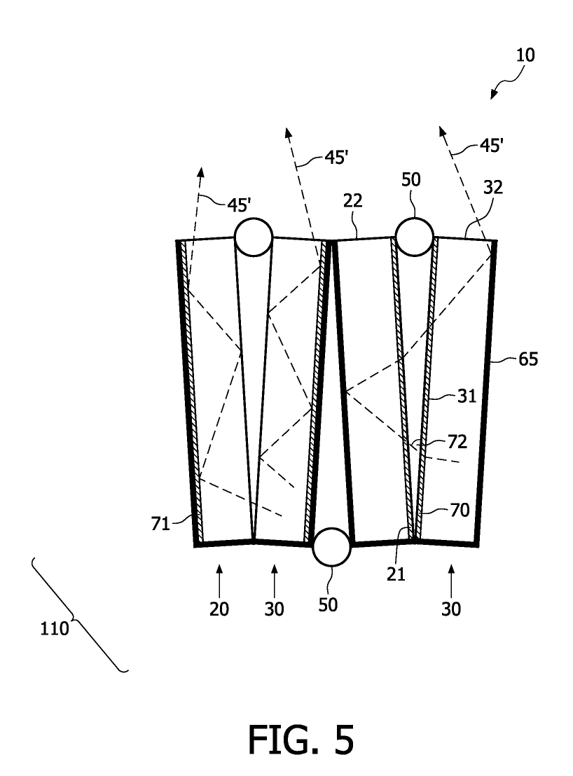

In FIG. 5 another embodiment of the light emitting device 10 is shown, being arranged in the compact position 110. Two of the sections 20, 30 comprise a surface layer 70. The surface layer 70 is superimposed onto the bottom side 21, 31 of the sections 20, 30. Aim of the surface layer 70 is to deflect the artificial light 45 emitted by the organic light emitting layer 43. By deflecting the artificial light 45 towards the side surface 22, 32 the amount of artificial light 45′ leaving the named side surfaces 22, 32 is enhanced. To achieve the deflection of the artificial light 45 the surface layer 70 may comprise a structured surface, which preferably comprises a plurality of micro-prisms. If artificial light 45 is e.g. generated within the section 30 it flows through the bottom side 31, is deflected by the structured surface and emitted under an angle 72 with respect to the bottom side 31. The so deflected light 45 is than going to enter the—in the shown embodiment—first section 20 and may well be reflected on one of the layers of the stack of layers 15. Subsequent another deflection in the surface layer 70 of the first section 20 may occur so that the artificial light 45 in the end leaves the side surface 32 in a more or less vertical manner with respect to the light emitting device 10.

To enhance the amount of artificial light 45 being emitted through one of the side surfaces 22, 23 the second electrode layer 40 may comprise a coating 71, which is reflecting the artificial light 45 as shown in the two left sections 20, 30 in FIG. 5. Thus, the chance of leaving the first 20 and/or second section 30 through one of the side surfaces 22, 32 is enhanced.

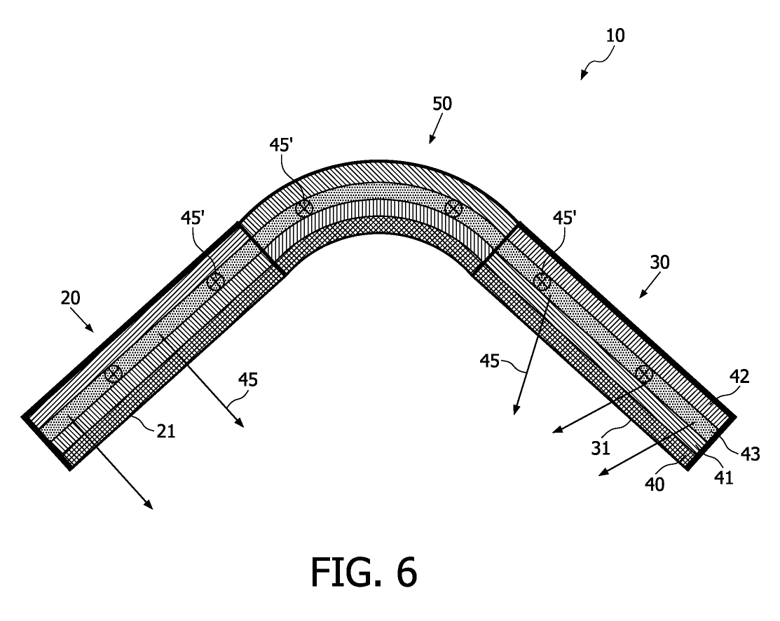

In FIG. 6 a cross section of another embodiment of the light emitting device 10 is shown. In the prior shown embodiments the first and the second section 20, 30 are individual pieces, which are connected through a connection mean 50. In contrast to that the light emitting device 10 shown in FIG. 6 is one-piece. Therefore the distinction between first and second section is arbitrary. As each section 20, 30 and the connection mean 50 are build on one flexible one piece foil 40 on which the OLED structure is superimposed, there is no real distinction between connection mean 50 and the sections 20, 30. All named arbitrary sections and the connection mean emit artificial light 45, 45′. In the shown embodiment the side surfaces 22, 32 through which the artificial light 45 leaves the light emitting device 10 are arranged in the plane of the drawing. Therefore the artificial light 45′ leaves the light emitting device 10 perpendicular to the artificial light 45, emitted through the bottom side 21, 31. In the compact position 110 the shown light emitting device 10 comprises a cylindrical shape. By uncoiling the light emitting device, the expanded position 100 is achieved.

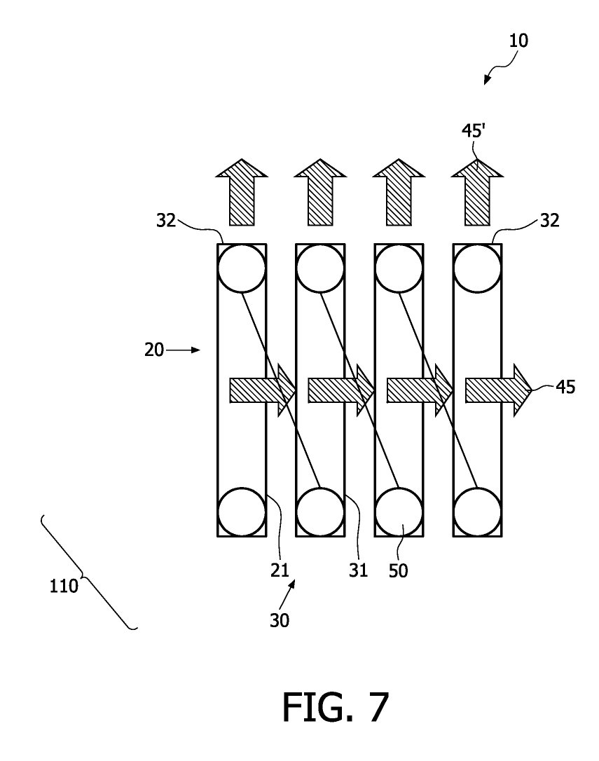

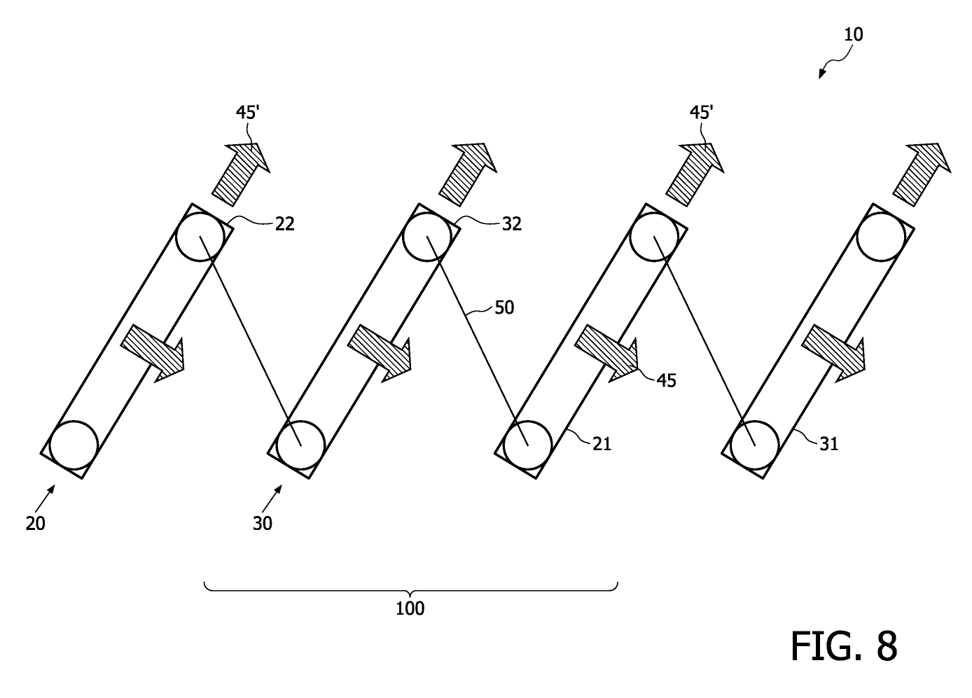

In the FIGS. 7 and 8 another embodiment of the light emitting device 10 is shown. In the compact position 110 shown in FIG. 7 the sections 20, 30 are aligned parallel to each other. Artificial light 45, 45′ may leave the light emitting device 10 through the bottom sides 21, 31 as well as through the side surfaces 22, 32. In the expanded position 100 shown in FIG. 8 the sections 20, 30 are arranged with a distance to each other due to the connection mean 50.

### LIST OF NUMERALS

10 light emitting device
15 stack of layers
20 first section
21 bottom side of the first section
22 side surface of the first section
23 rim
30 second section
31 bottom side of the second section
32 side surface of the second section
33 rim
40 basic layer
41 first electrode layer
42 second electrode layer
43 organic light-emitting layer
44 top layer
45,45′ artificial light
50 connection mean
60 handhold element
65 frame mean
70 surface layer
71 reflective coating of the second electrode layer 42
72 angle
100 expanded position
110 compact position

1. A light emitting device having at least one first and at least one second section, wherein
the first section borders the second section and each section comprises a bottom side and at least one side surface,
each section comprises a stack of layers of a substrate, with a basic layer, a first electrode layer, a second electrode layer and an organic light-emitting layer, wherein the organic light-emitting layer is sandwiched between the first electrode layer (41) and the second electrode layer,
the organic light-emitting layer is emitting an artificial light,
in an expanded position the first section and the second section are longish stretched and the artificial light is primarily emitted through the bottom sides of the first section and the second section, and
in a compact position the first section faces the second section at least partially in such a way, that the artificial light is primarily emitted through the side surfaces of the first section and the second section.

2. A light emitting device according to claim 1, wherein a connection mean connects the first section and the second section.

3. A light emitting device according to claim 2, wherein the connection mean (50) is a hinges, a stamping, a cutting or a foil.

4. A light emitting device according to claim 1, wherein the first section and the second section a flexible one-piece foil.

5. A light emitting device according to claim 1, wherein the bottom side of the first and/or second section is covered with a surface layer, enhancing the amount of artificial light (45,45′), being emitted under an angle with respect to the bottom side.

6. A light emitting device according to claim 1, wherein the first and/or the second section comprise a rim covered with a reflective layer.

7. A light emitting device according to claim 1, wherein the second electrode layer comprises a material for reflecting the artificial light.

8. (canceled)

9. A light emitting device according to claim 1, wherein the first and/or the second section comprises a handhold element arranged in such a way, that in the compact position the light emitting device forms a torch.

10. A light emitting device according to claim 1, wherein the handhold element comprises a power source and/or a control device and/or a switch device.
